(19) United States
(12) Patent Application Publication
(10) Pub. No.: US 2024/0313129 A1
(43) Pub. Date: Sep. 19, 2024

(54) SCHOTTKY BARRIER DIODE

(71) Applicant: TDK Corporation, Tokyo (JP)

(72) Inventors: Jun ARIMA, Tokyo (JP); Minoru FUJITA, Tokyo (JP); Katsumi KAWASAKI, Tokyo (JP); Jun HIRABAYASHI, Tokyo (JP)

(21) Appl. No.: 18/676,077

(22) Filed: May 28, 2024

Related U.S. Application Data
(63) Continuation of application No. PCT/JP2022/030765, filed on Aug. 12, 2022.

(30) Foreign Application Priority Data
Nov. 29, 2021 (JP) 2021-193059

(51) Int. Cl. H01L 29/872; H01L 29/24

(52) U.S. Cl. CPC H01L 29/8725; H01L 29/24

(57) ABSTRACT

Disclosed herein is a Schottky barrier diode that includes a semiconductor substrate made of gallium oxide, a drift layer made of gallium oxide and provided on the semiconductor substrate, an anode electrode brought into Schottky contact with the drift layer, and a cathode electrode brought into ohmic contact with the semiconductor substrate. The drift layer has a center trench filled with the anode electrode. A bottom surface of the center trench is covered with an insulating film without being in contact with the anode electrode. At least a part of a side surface of the center trench is brought into Schottky contact with the anode electrode.

### CROSS-REFERENCE OF RELATED APPLICATIONS

This application is a Continuation of International Patent Application No. PCT/JP2022/030765, filed on Aug. 12, 2022, which in turn claims the benefit of Japanese Patent Application No. 2021-193059, filed on Nov. 29, 2021, the entire disclosure of which Applications are incorporated by reference herein.

### BACKGROUND OF THE ART

The present disclosure relates to a Schottky barrier diode and, more particularly, to a Schottky barrier diode using gallium oxide.

A Schottky barrier diode is a rectifying element utilizing a Schottky barrier generated due to bonding between metal and a semiconductor and is lower in forward voltage and higher in switching speed than a normal diode having a PN junction. Thus, the Schottky barrier diode is sometimes utilized as a switching element for a power device.

When the Schottky barrier diode is utilized as a switching element for a power device, it is necessary to ensure a sufficient backward withstand voltage, so that silicon carbide (SiC), gallium nitride (GaN), or gallium oxide (Ga₂O₃) having a larger band gap is sometimes used in place of silicon (Si). Among them, gallium oxide has a very large band gap (4.8 eV to 4.9 eV) and a large breakdown field of about 8 MV/cm, so that a Schottky barrier diode using gallium oxide is very promising as the switching element for a power device. An example of the Schottky barrier diode using gallium oxide is described in JP 2017-199869 A.

In the Schottky barrier diode described in JP 2017-199869 A, a plurality of trenches are formed in a gallium oxide layer and filled with a part of an anode electrode through an insulating film. With this structure, when a backward voltage is applied, a mesa region positioned between adjacent trenches becomes a depletion layer, so that a channel region of a drift layer is pinched off. Thus, a leak current upon application of the backward voltage can be significantly reduced.

However, when a trench having inner wall covered with an insulating layer is formed in the drift layer, ON-resistance of the Schottky barrier diode disadvantageously increases. To reduce the ON-resistance, the impurity concentration of the drift layer should be increased; however, this reduces a backward withstand voltage.

### SUMMARY

It is desirable to provide a Schottky barrier diode using gallium oxide, capable of reducing the ON-resistance while ensuring a sufficient backward withstand voltage.

A Schottky barrier diode according to the present disclosure includes: a semiconductor substrate made of gallium oxide; a drift layer made of gallium oxide and provided on the semiconductor substrate; an anode electrode brought into Schottky contact with the drift layer; and a cathode electrode brought into ohmic contact with the semiconductor substrate. The drift layer has a center trench filled with the anode electrode. A bottom surface of the center trench is covered with an insulating film without being in contact with the anode electrode. At least a part of a side surface of the center trench is brought into Schottky contact with the anode electrode.

### BRIEF DESCRIPTION OF THE DRAWINGS

FIG. 1A is a schematic plan view illustrating the configuration of a Schottky barrier diode 1 according to a first embodiment of the present disclosure.

FIG. 1B is a schematic cross-sectional view taken along the line A-A in FIG. 1A.

FIGS. 2A to 2C are schematic cross-sectional views for explaining the positions of the inner walls of the center trench 61 and the outer trench 62 that are covered with the insulating film 70.

FIG. 3 is a schematic cross-sectional view illustrating the configuration of a Schottky barrier diode 2 according to a second embodiment of the present disclosure.

FIG. 4 is a schematic cross-sectional view illustrating the configuration of a Schottky barrier diode 3 according to a third embodiment of the present disclosure.

FIG. 5 is a schematic cross-sectional view illustrating the configuration of a Schottky barrier diode 4 according to a fourth embodiment of the present disclosure.

FIG. 6 is a schematic cross-sectional view illustrating the configuration of a Schottky barrier diode 5 according to a fifth embodiment of the present disclosure.

FIG. 7 is a schematic cross-sectional view illustrating the configuration of a Schottky barrier diode 6 according to a sixth embodiment of the present disclosure.

FIG. 8 is a schematic cross-sectional view illustrating the configuration of a Schottky barrier diode 7 according seventh embodiment of the present disclosure.

FIG. 9A is a schematic plan view illustrating the configuration of a Schottky barrier diode 8 according to an eighth embodiment of the present disclosure.

FIG. 9B is a schematic cross-sectional view taken along the line A-A in FIG. 9A.

FIG. 10 is a schematic cross-sectional view illustrating the configuration of a Schottky barrier diode 9 according to a ninth embodiment of the present disclosure.

FIG. 11 is a schematic cross-sectional view illustrating the configuration of a Schottky barrier diode 10 according to a tenth embodiment of the present disclosure.

FIG. 12 is a schematic cross-sectional view illustrating the configuration of a Schottky barrier diode 11 according to an eleventh embodiment of the present disclosure.

FIG. 13A is a schematic plan view illustrating the configuration of a Schottky barrier diode 12 according to a twelfth embodiment of the present disclosure.

FIG. 13B is a schematic cross-sectional view taken along the line A-A in FIG. 13A.

FIG. 14A is a schematic plan view illustrating the configuration of a Schottky barrier diode 13 according to a thirteenth embodiment of the present disclosure.

FIG. 14B is a schematic cross-sectional view taken along the line A-A in FIG. 14A.

FIG. 15A is a schematic plan view illustrating the configuration of a Schottky barrier diode 14 according to a fourteenth embodiment of the present disclosure.

FIG. 15B is a schematic cross-sectional view taken along the line A-A in FIG. 15A.

FIG. 16A is a schematic plan view illustrating the configuration of a Schottky barrier diode 15 according to a fifteenth embodiment of the present disclosure.

FIG. 16B is a schematic cross-sectional view taken along the line A-A in FIG. 16A.

FIG. 17A is a schematic plan view illustrating the configuration of a Schottky barrier diode 16 according to a sixteenth embodiment of the present disclosure.

FIG. 17B is a schematic cross-sectional view taken along the line A-A in FIG. 17A.

FIG. 18 is a graph showing the simulation results of the examples.

### DETAILED DESCRIPTION OF THE EMBODIMENTS

Hereinafter, embodiments of the present disclosure will be described in detail with reference to the accompanying drawings.

### First Embodiment

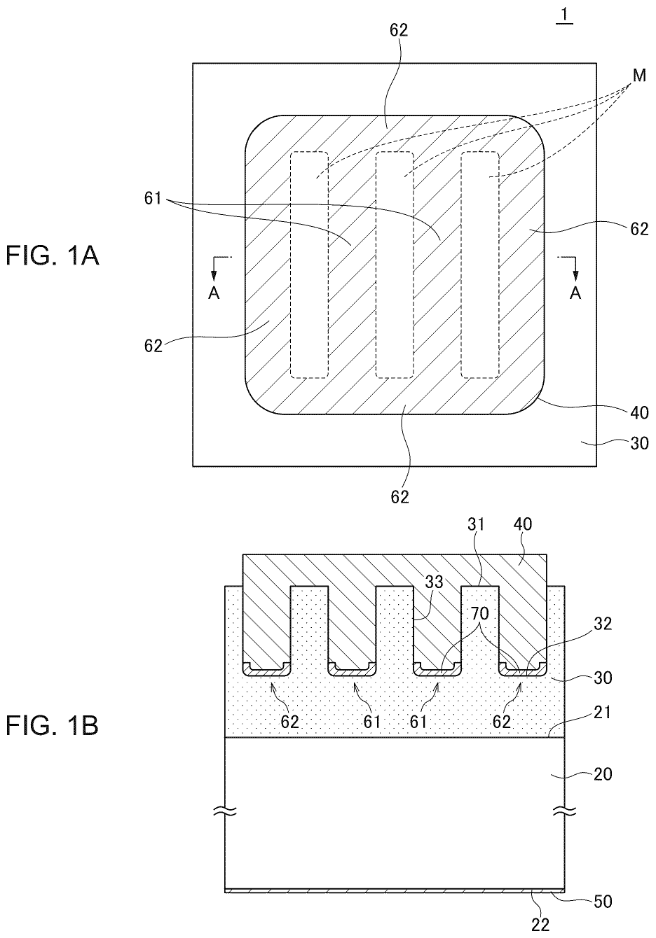

FIG. 1A is a schematic plan view illustrating the configuration of a Schottky barrier diode 1 according to a first embodiment of the present disclosure. FIG. 1B is a schematic cross-sectional view taken along the line A-A in FIG. 1A.

As illustrated in FIGS. 1A and 1B, the Schottky barrier diode 1 according to the first embodiment has a semiconductor substrate 20 and a drift layer 30, both of which are made of gallium oxide (β-Ga₂O₃). The semiconductor substrate 20 and drift layer 30 are each introduced with silicon (Si) or tin (Sn) as an n-type dopant. The concentration of the dopant is higher in the semiconductor substrate 20 than in the drift layer 30, whereby the semiconductor substrate 20 and the drift layer 30 function as an n⁺ layer and an n-layer, respectively.

The semiconductor substrate 20 is obtained by cutting a bulk crystal formed using a melt-growing method and has a thickness of about 250 μm. The planar size of the semiconductor substrate 20 is not particularly limited and is generally selected in accordance with the amount of current flowing in the element. For example, when the maximum amount of forward current is about 20 A, the planar size may be set to about 2.4 mm×2.4 mm.

The semiconductor substrate 20 has an upper surface 21 positioned on the upper surface side in a mounted state and a back surface 22 positioned opposite the upper surface 21, on the lower surface side in a mounted state. The drift layer 30 is formed on the entire upper surface 21. The drift layer 30 is a thin film obtained by epitaxially growing gallium oxide on the upper surface 21 of the semiconductor substrate 20 using a reactive sputtering method, a PLD method, an MBE method, an MOCVD method, or an HVPE method. The film thickness of the drift layer 30 is not particularly limited and is generally selected in accordance with the backward withstand voltage of the element. For example, in order to ensure a withstand voltage of about 600V, the film thickness may be set to about 7 μm.

There is formed, on an upper surface 31 of the drift layer 30, an anode electrode 40 which is brought into Schottky contact with the drift layer 30. The anode electrode 40 is formed of metal such as platinum (Pt), palladium (Pd), gold (Au), nickel (Ni), molybdenum (Mo), or Copper (Cu). The anode electrode 40 may have a multilayer structure of different metal films, such as Pt/Au, Pt/Al, Pd/Au, Pd/Al, Pt/Ti/Au, or Pd/Ti/Au. On the other hand, there is formed, on the back surface 22 of the semiconductor substrate 20, a cathode electrode 50 which is brought into ohmic contact with the semiconductor substrate 20. The cathode electrode 50 is formed of metal such as titanium (Ti). The cathode electrode 50 may have a multilayer structure of different metal films, such as Ti/Au or Ti/Al.

In the present embodiment, a center trench 61 and an outer peripheral trench 62 are formed in the drift layer 30. The center and outer peripheral trenches 61 and 62 are each formed at a position overlapping the anode electrode 40 in a plan view and are each filled with the same metal material as the anode electrode 40. The center trench 61 is sandwiched between a region M mesa constituting a part of the drift layer 30. The outer peripheral trench 62 surrounds the mesa region M and center trench 61 in a ring. The center and outer peripheral trenches 61 and 62 need not be completely separated from each other, but may be connected to each other as illustrated in FIG. 1A. The depths of the center and outer peripheral trenches 61 and 62 may be the same or different. The mesa region M constitutes a part of the drift layer 30 that is partitioned by the center and outer peripheral trenches 61 and 62 and becomes a depletion layer when a backward voltage is applied between the anode and cathode electrodes 40 and 50. Thus, a channel region of the drift layer 30 is pinched off, so that a leak current upon application of the backward voltage is significantly reduced.

A bottom surface 32 of the inner wall of each of the center and outer peripheral trenches 61 and 62 is covered with an insulating film 70, whereas a side surface 33 of the inner wall of each of the center and outer peripheral trenches 61 and 62 is not covered therewith. Accordingly, the bottom surface 32 of each of the center and outer peripheral trenches 61 and 62 does not contact the anode electrode 40, whereas the side surface 33 of each of the center and outer peripheral trenches 61 and 62 is brought into Schottky contact with the anode electrode 40 without being covered with the insulating film 70. This allows the drift layer 30 and anode electrode 40 to be brought into Schottky contact with each other not only at the upper surface 31 of the drift layer 30 but also at the side surface 33 of each of the center and outer peripheral trenches 61 and 62, with the result that ON-resistance of the Schottky barrier diode 1 decreases as compared with when the entire inner wall of each of the center and outer peripheral trenches 61 and 62 is covered with the insulating film 70. Further, the dopant concentration of the drift layer 30 can be reduced to about 3×10¹⁶ cm⁻³, thereby preventing a reduction in backward withstand voltage. The material of the insulating film 70 may be an insulating material having a high dielectric constant, such as HfO₂ or Al₂O₃. This improves withstand voltage effect.

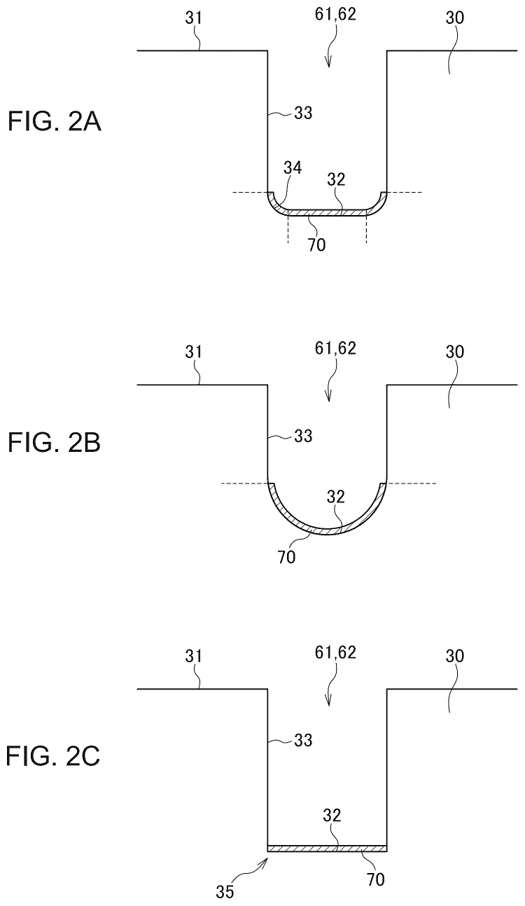

As illustrated in FIG. 2A, when the bottom surface 32 of each of the center and outer peripheral trenches 61 and 62 is horizontal, and a portion between the horizontal bottom surface 32 and the vertical side surface 33 is a curved surface 34, the bottom surface 32 and curved surface 34 need to be covered with the insulating film 70. Further, as illustrated in FIG. 2B, when the bottom surface 32 of each of the center and outer peripheral trenches 61 and 62 is entirely curved, the entire curved bottom surface 32 needs to be covered with the insulating film 70.

Furthermore, as illustrated in FIG. 2C, when the bottom surface 32 of each of the center and outer peripheral trenches 61 and 62 is horizontal, and a right-angled corner portion 35 exists between the horizontal bottom surface 32 and the vertical side surface 33, the bottom surface 32 and corner portion 35 need to be covered with the insulating film 70.

As described above, in the Schottky barrier diode 1 according to the present embodiment, the anode electrode 40 is brought into Schottky contact with the side surface 33 of each of the center and outer peripheral trenches 61 and 62, thereby making it possible to reduce the ON-resistance as compared with when the entire inner wall of each of the center and outer peripheral trenches 61 and 62 is covered with the insulating film 70.

### Second Embodiment

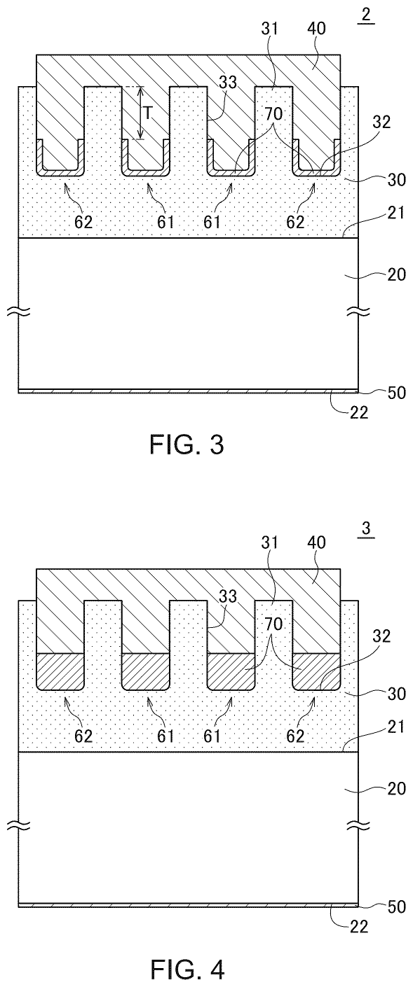

FIG. 3 is a schematic cross-sectional view illustrating the configuration of a Schottky barrier diode 2 according to a second embodiment of the present disclosure.

As illustrated in FIG. 3, the Schottky barrier diode 2 according to the second embodiment differs from the Schottky barrier diode 1 according to the first embodiment in that a part of the side surface 33 of each of the center and outer peripheral trenches 61 and 62 that is positioned in the vicinity of the bottom surface 32 is covered with the insulating film 70. Other basic configurations are the same as those of the Schottky barrier diode 1 according to the first embodiment, so the same reference numerals are given to the same elements, and overlapping description will be omitted. In the present embodiment, a depth T of the anode electrode 40, which is the range where the anode electrode 40 contacts the side surface 33 of each of the center and outer peripheral trenches 61 and 62, can be adjusted depending on the height position of the insulating film 70.

### Third Embodiment

FIG. 4 is a schematic cross-sectional view illustrating the configuration of a Schottky barrier diode 3 according to a third embodiment of the present disclosure.

As illustrated in FIG. 4, the Schottky barrier diode 3 according to the third embodiment differs from the Schottky barrier diode 2 according to the second embodiment in that the insulating film 70 has a substantially flat upper surface and is filled in the bottom portion of each of the center and outer peripheral trenches 61 and 62. Other basic configurations are the same as those of the Schottky barrier diode 2 according to the second embodiment, so the same reference numerals are given to the same elements, and overlapping description will be omitted. When a part of the side surface 33 of each of the center and outer peripheral trenches 61 and 62 that is positioned in the vicinity of the bottom surface 32 is covered with the insulating film 70, the entire bottom portion of each of the center and outer peripheral trenches 61 and 62 may be filled with the insulating film 70.

### Fourth Embodiment

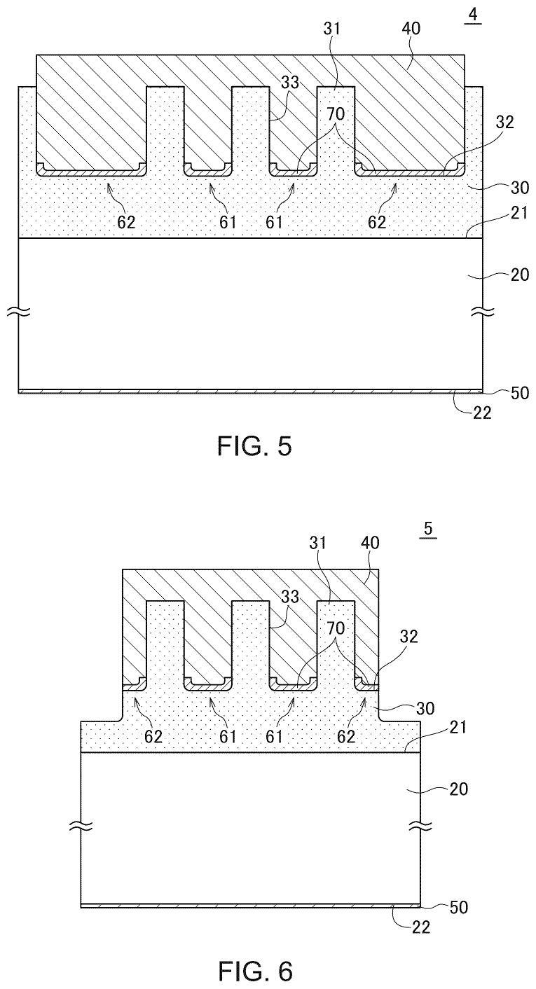

FIG. 5 is a schematic cross-sectional view illustrating the configuration of a Schottky barrier diode 4 according to a fourth embodiment of the present disclosure.

As illustrated in FIG. 5, the Schottky barrier diode 4 according to the fourth embodiment differs from the Schottky barrier diode 1 according to the first embodiment in that the outer peripheral trench 62 is made larger in width than the center trench 61. Other basic configurations are the same as those of the Schottky barrier diode 1 according to the first embodiment, so the same reference numerals are given to the same elements, and overlapping description will be omitted. By thus increasing the width of the outer peripheral trench 62, it is possible to relax the electric field concentration in the vicinity of the bottom portion of the outer peripheral trench 62 upon application of a backward voltage.

### Fifth Embodiment

FIG. 6 is a schematic cross-sectional view illustrating the configuration of a Schottky barrier diode 5 according to a fifth embodiment of the present disclosure.

As illustrated in FIG. 6, the Schottky barrier diode 5 according to the fifth embodiment differs from the Schottky barrier diode 1 according to the first embodiment in that a part of the drift layer 30 that is positioned outside the outer peripheral trench 62 is removed. Other basic configurations are the same as those of the Schottky barrier diode 1 according to the first embodiment, so the same reference numerals are given to the same elements, and overlapping description will be omitted. An On-current hardly flows in the part of the drift layer 30 that is positioned outside the outer peripheral trench 62, so that the drift layer 30 may be removed at this position as in the present embodiment.

### Sixth Embodiment

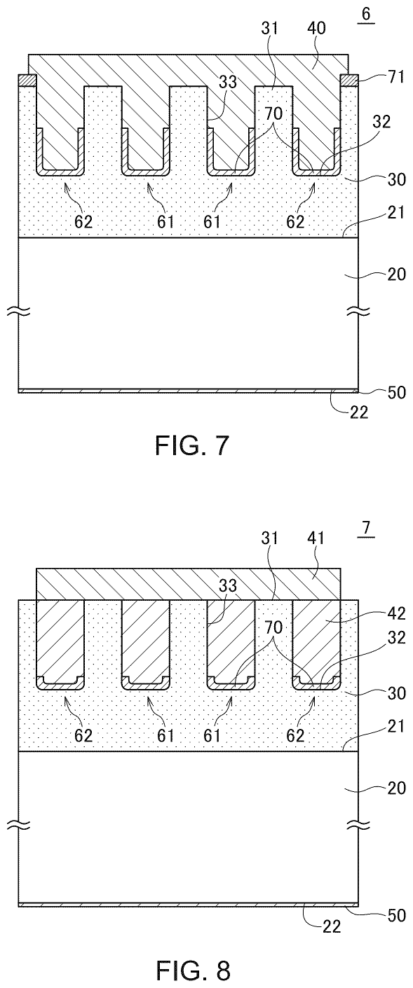

FIG. 7 is a schematic cross-sectional view illustrating the configuration of a Schottky barrier diode 6 according to a sixth embodiment of the present disclosure.

As illustrated in FIG. 7, the Schottky barrier diode 6 according to the sixth embodiment differs from the Schottky barrier diode 1 according to the first embodiment in that an insulating film 71 is provided between the upper surface 31 of the part of the drift layer 30 that is positioned outside the outer peripheral trench 62 and the anode electrode 40. Other basic configurations are the same as those of the Schottky barrier diode 1 according to the first embodiment, so the same reference numerals are given to the same elements, and overlapping description will be omitted. According to the present embodiment, a so-called field plate structure is achieved by the presence of the insulating film 71, allowing more relaxation of an electric field to be applied to the bottom portion of the outer peripheral trench 62. The material of the insulating film 71 may be a material having a high withstand voltage, such as SiO₂ or Al₂O₃. This improves withstand voltage effect.

### Seventh Embodiment

FIG. 8 is a schematic cross-sectional view illustrating the configuration of a Schottky barrier diode 7 according to a seventh embodiment of the present disclosure.

As illustrated in FIG. 8, the Schottky barrier diode 7 according to the seventh embodiment differs from the Schottky barrier diode 1 according to the first embodiment in that an anode electrode 41 covering the upper surface of the drift layer 30 and an anode electrode 42 filled in the center and outer peripheral trenches 61 and 62 are made of mutually different metal materials. Other basic configurations are the same as those of the Schottky barrier diode 1 according to the first embodiment, so the same reference numerals are given to the same elements, and overlapping description will be omitted. Such a structure can be obtained by, for example, forming the anode electrode 42 and the anode electrode 41 by electrolytic plating and vapor deposition, respectively. Such a manufacturing method makes it hard to generate a void in the anode electrode 42 filled in the center and outer peripheral trenches 61 and 62.

### Eighth Embodiment

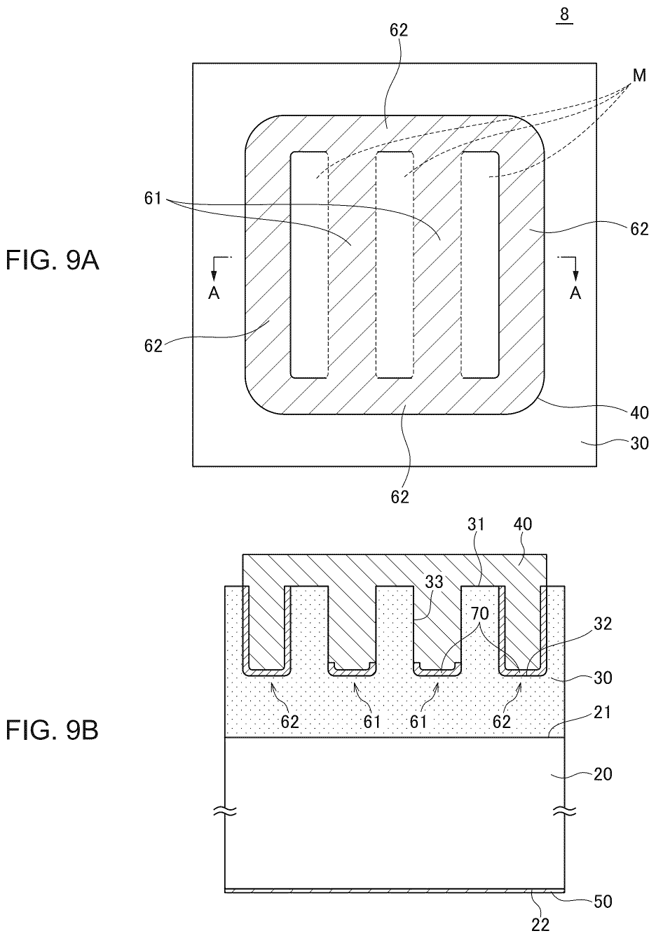

FIG. 9A is a schematic plan view illustrating the configuration of a Schottky barrier diode 8 according to an eighth embodiment of the present disclosure. FIG. 9B is a schematic cross-sectional view taken along the line A-A in FIG. 9A.

As illustrated in FIGS. 9A and 9B, the Schottky barrier diode 8 according to the eighth embodiment differs from the Schottky barrier diode 1 according to the first embodiment in that the entire inner wall of the outer peripheral trench 62 is covered with the insulating film 70. Other basic configurations are the same as those of the Schottky barrier diode 1 according to the first embodiment, so the same reference numerals are given to the same elements, and overlapping description will be omitted. In FIG. 9A, a part of the surface of the mesa region M that is brought into Schottky contact with the drift layer 30 is denoted by a dashed line, while a part of the surface of the mesa region M that is covered with the insulating film 70 is denoted by a solid line. This can further increase a backward withstand voltage.

### Ninth Embodiment

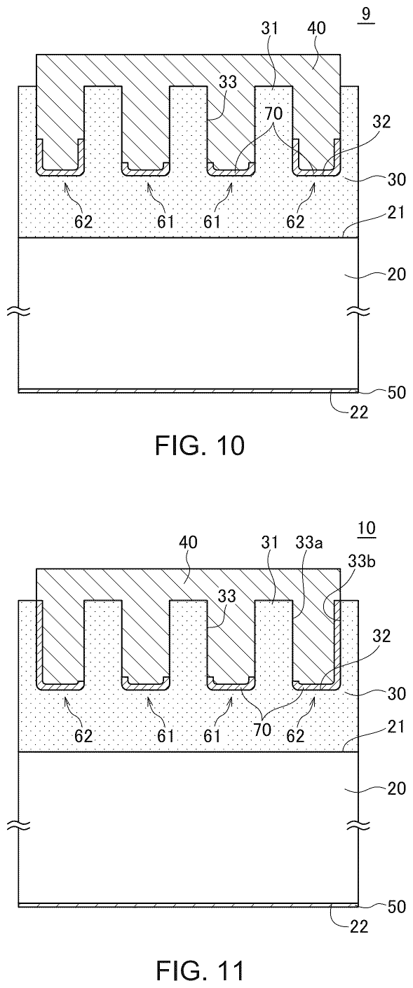

FIG. 10 is a schematic cross-sectional view illustrating the configuration of a Schottky barrier diode 9 according to a ninth embodiment of the present disclosure.

As illustrated in FIG. 10, the Schottky barrier diode 9 according to the ninth embodiment differs from the Schottky barrier diode 8 according to the eighth embodiment in that the height position of the insulating film 70 covering the side surface 33 of the outer peripheral trench 62 is lower than that in the Schottky barrier diode 8 according to the eighth embodiment to thereby bring a part of the side surface 33 of the outer peripheral trench 62 into Schottky contact with the anode electrode 40. Other basic configurations are the same as those of the Schottky barrier diode 8 according to the eighth embodiment, so the same reference numerals are given to the same elements, and overlapping description will be omitted. According to the present embodiment, the ON-resistance can be reduced more than that in the Schottky barrier diode 8 according to the eighth embodiment while a backward withstand voltage is increased.

### Tenth Embodiment

FIG. 11 is a schematic cross-sectional view illustrating the configuration of a Schottky barrier diode 10 according to a tenth embodiment of the present disclosure.

As illustrated in FIG. 11, the Schottky barrier diode 10 according to the tenth embodiment differs from the Schottky barrier diode 8 according to the eighth embodiment in that the insulating film 70 on an inner side surface 33a constituting the inner side of the side surface 33 of the outer peripheral trench 62 is removed. An outer side surface 33b constituting the outer side of the side surface 33 of the outer peripheral trench 62 is entirely covered with the insulating film 70. Other basic configurations are the same as those of the Schottky barrier diode 8 according to the eighth embodiment, so the same reference numerals are given to the same elements, and overlapping description will be omitted. In the present embodiment as well, the ON-resistance can be reduced more than that in the Schottky barrier diode 8 according to the eighth embodiment while a backward withstand voltage is increased.

### Eleventh Embodiment

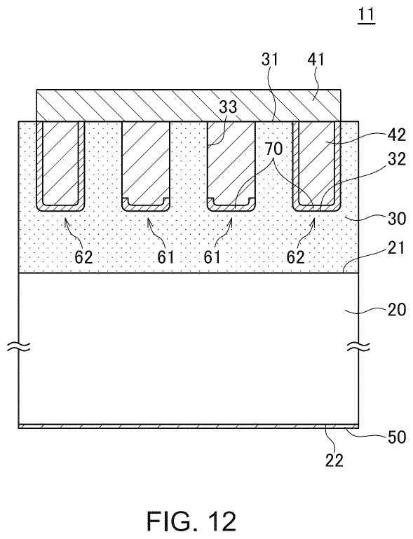

FIG. 12 is a schematic cross-sectional view illustrating the configuration of a Schottky barrier diode 11 according to an eleventh embodiment of the present disclosure.

As illustrated in FIG. 12, the Schottky barrier diode 11 according to the eleventh embodiment differs from the Schottky barrier diode 8 according to the eighth embodiment in that the anode electrode 41 covering the upper surface of the drift layer 30 and the anode electrode 42 filled in the center and outer peripheral trenches 61 and 62 are made of mutually different metal materials. Other basic configurations are the same as those of the Schottky barrier diode 8 according to the eighth embodiment, so the same reference numerals are given to the same elements, and overlapping description will be omitted. Such a structure can be obtained by, for example, forming the anode electrode 42 and the anode electrode 41 by electrolytic plating and vapor deposition, respectively. Such a manufacturing method makes it hard to generate a void in the anode electrode 42 filled in the center and outer peripheral trenches 61 and 62.

### Twelfth Embodiment

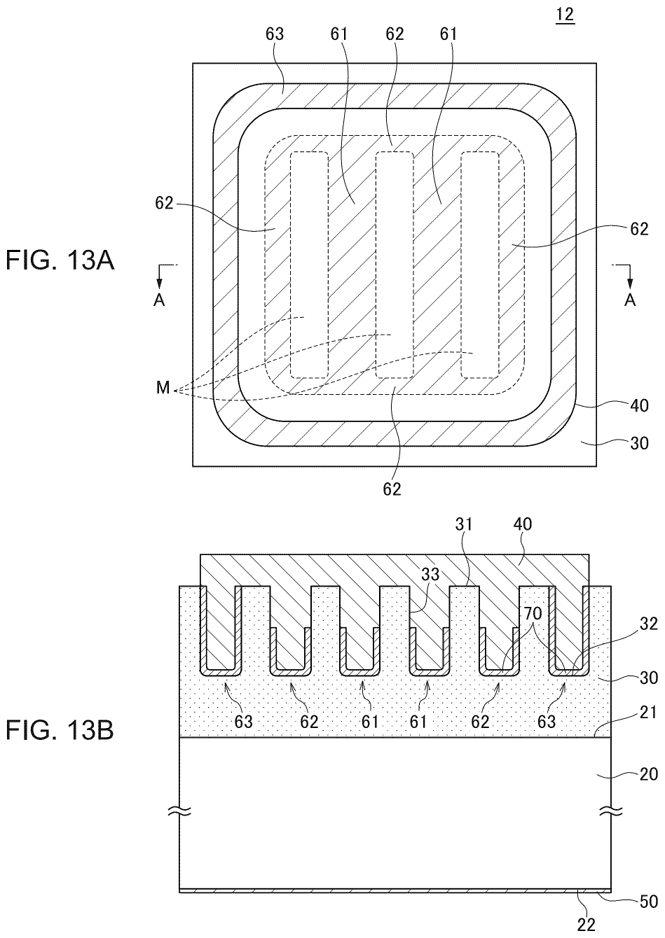

FIG. 13A is a schematic plan view illustrating the configuration of a Schottky barrier diode 12 according to a twelfth embodiment of the present disclosure. FIG. 13B is a schematic cross-sectional view taken along the line A-A in FIG. 13A.

As illustrated in FIGS. 13A and 13B, the Schottky barrier diode 12 according to the twelfth embodiment differs from the Schottky barrier diode 2 according to the second embodiment in that another outer peripheral trench 63 surrounding the outer peripheral trench 62 is provided in the drift layer 30 and that the entire inner wall thereof is covered with the insulating film 70. The outer peripheral trench 63 is formed independently of the outer peripheral trench 62. Other basic configurations are the same as those of the Schottky barrier diode 1 according to the first embodiment, so the same reference numerals are given to the same elements, and overlapping description will be omitted. In FIG. 13A, a part of the surface of the mesa region M that is brought into Schottky contact with the drift layer 30 is denoted by a dashed line, while a part of the surface of the mesa region M that is covered with the insulating film 70 is denoted by a solid line. By thus providing the outer peripheral trench 63 different from the outer peripheral trench 62 in the drift layer 30 and covering the entire inner wall thereof with the insulating film 70, it is possible to relax the electric field concentration in the vicinity of the bottom portion of the center and outer peripheral trenches 61 and 62 upon application of a backward voltage.

### Thirteenth Embodiment

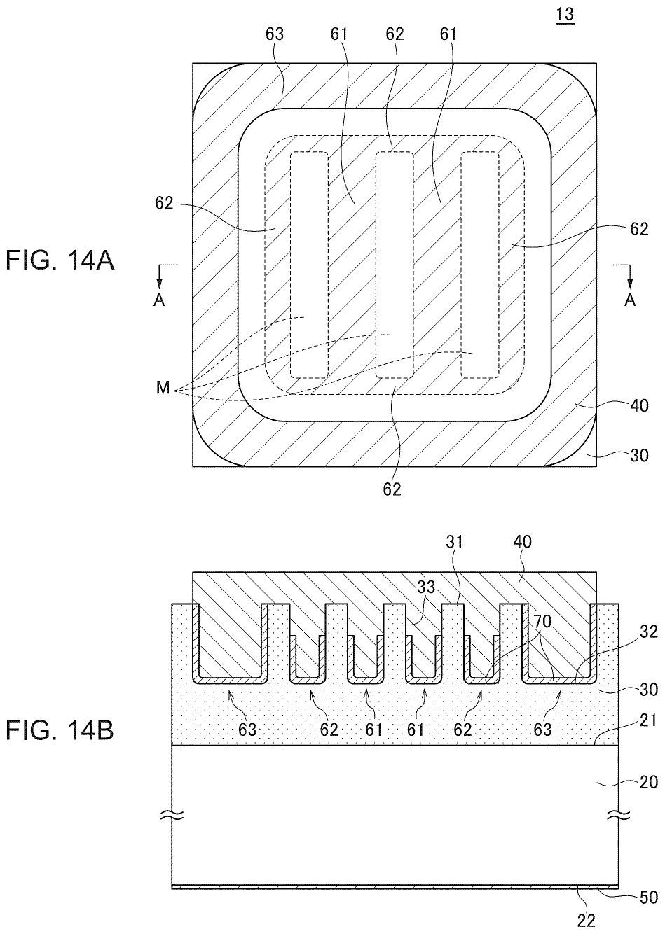

FIG. 14A is a schematic plan view illustrating the configuration of a Schottky barrier diode 13 according to a thirteenth embodiment of the present disclosure. FIG. 14B is a schematic cross-sectional view taken along the line A-A in FIG. 14A.

As illustrated in FIGS. 14A and 14B, the Schottky barrier diode 13 according to the thirteenth embodiment differs from the Schottky barrier diode 12 according to the twelfth embodiment in that the outer peripheral trench 63 is made larger in width than the center and outer peripheral trenches 61 and 62. Other basic configurations are the same as those of the Schottky barrier diode 12 according to the twelfth embodiment, so the same reference numerals are given to the same elements, and overlapping description will be omitted. By thus increasing the width of the outer peripheral trench 63, it is possible to relax the electric field concentration in the vicinity of the bottom portion of the outer peripheral trench 63 upon application of a backward voltage.

### Fourteenth Embodiment

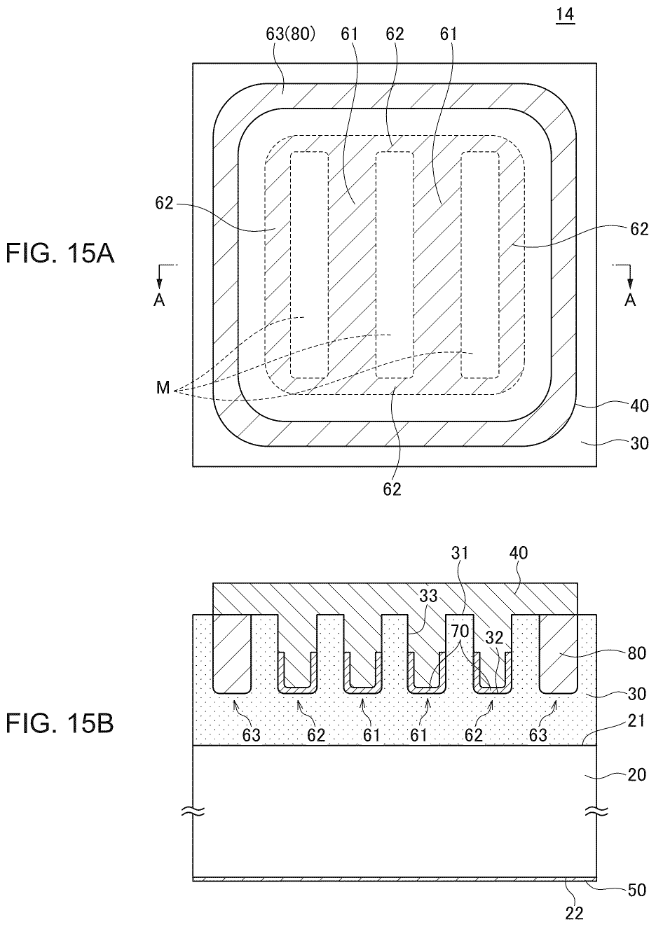

FIG. 15A is a schematic plan view illustrating the configuration of a Schottky barrier diode 14 according to a fourteenth embodiment of the present disclosure. FIG. 15B is a schematic cross-sectional view taken along the line A-A in FIG. 15A.

As illustrated in FIGS. 15A and 15B, the Schottky barrier diode 14 according to the fourteenth embodiment differs from the Schottky barrier diode 12 according to the twelfth embodiment in that the outer peripheral trench 63 is filled with a p-type semiconductor material 80. The p-type semiconductor material 80 contacts the anode electrode 40. Other basic configurations are the same as those of the Schottky barrier diode 12 according to the twelfth embodiment, so the same reference numerals are given to the same elements, and overlapping description will be omitted. Examples of the p-type semiconductor material 80 include Si, GaAs, GaN, SiC, Ge, ZnSe, CdS, InP, SiGe, AlN, BN, AlGaN, NiO, Cu₂O, Ir₂O₃, Ag₂O. Among them, a p-type oxide semiconductor, such as NiO, is free from oxidation problems. By thus filling the outer peripheral trench 63 with the p-type semiconductor material 80, a depletion layer spreads around the outer peripheral trench 63 upon application of a backward voltage. Thus, upon application of a backward voltage, an electric field generated at the outer peripheral bottom portion of the outer peripheral trench 63 is relaxed.

### Fifteenth Embodiment

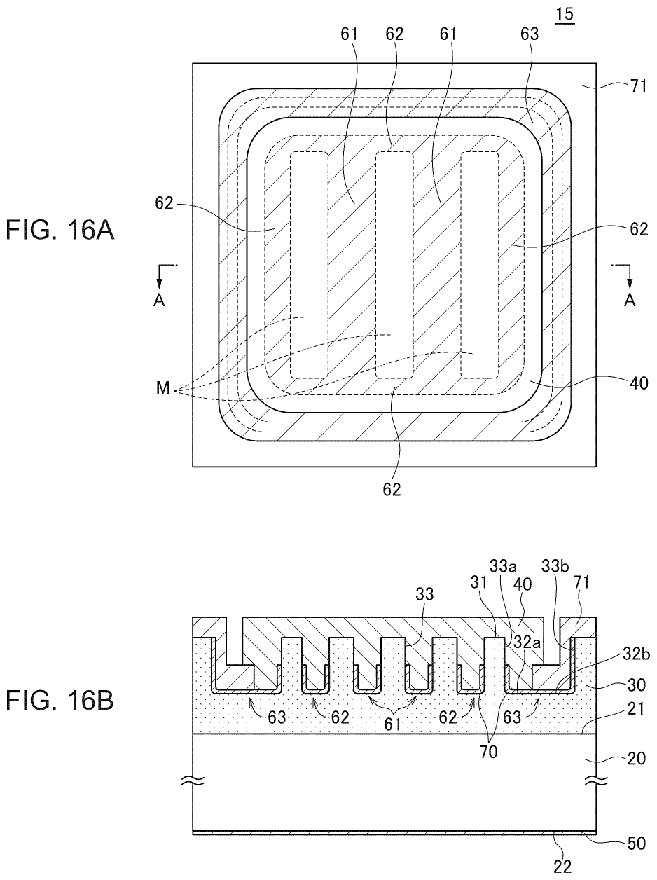

FIG. 16A is a schematic plan view illustrating the configuration of a Schottky barrier diode 15 according to a fifteenth embodiment of the present disclosure. FIG. 16B is a schematic cross-sectional view taken along the line A-A in FIG. 16A.

As illustrated in FIGS. 16A and 16B, the Schottky barrier diode 15 according to the fifteenth embodiment differs from the Schottky barrier diode 15 according to the thirteenth embodiment in that the upper surface 31 of the drift layer 30 positioned outside the outer peripheral trench 63, the outer side surface 33b of the outer peripheral trench 63, and an outer side bottom surface 32b of the outer peripheral trench 63 are covered with the insulating film 71. An inner side bottom surface 32a of the outer peripheral trench 63 is covered with the anode electrode 40 through the insulating film 70. The inner side surface 33a of the outer peripheral trench 63 is covered with the insulating film 70 at its lower portion close to the bottom surface 32 and contacts the anode electrode 40 at its upper portion. Other basic configurations are the same as those of the Schottky barrier diode 13 according to the thirteenth embodiment, so the same reference numerals are given to the same elements, and overlapping description will be omitted. The insulating films 70 and 71 may be made of the same or different insulating materials. With the above configuration, the ON-resistance can be reduced more than that in the Schottky barrier diode 13 according to the thirteenth embodiment while a backward withstand voltage is increased.

### Sixteenth Embodiment

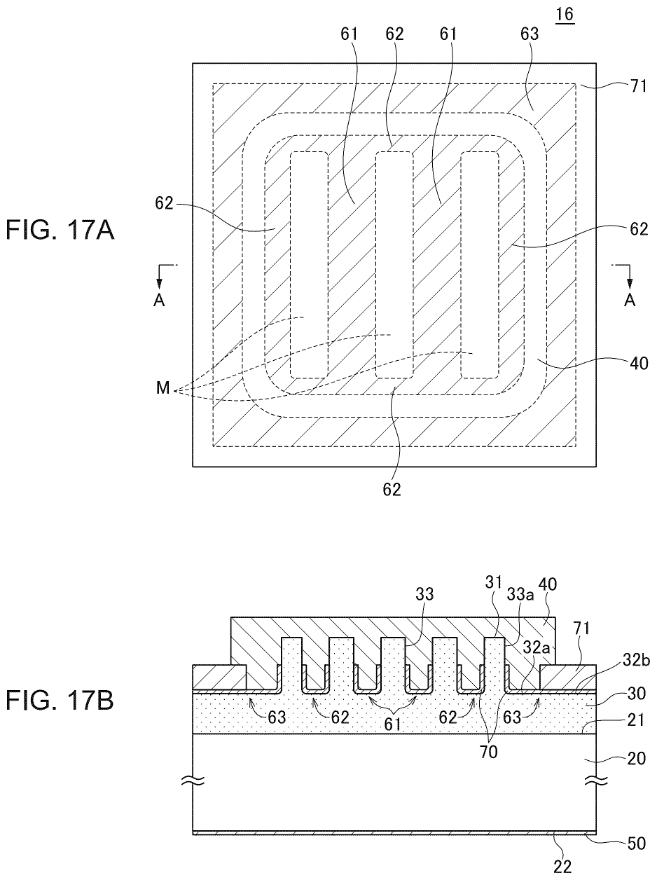

FIG. 17A is a schematic plan view illustrating the configuration of a Schottky barrier diode 16 according to a sixteenth embodiment of the present disclosure. FIG. 17B is a schematic cross-sectional view taken along the line A-A in FIG. 17A.

As illustrated in FIGS. 17A and 17B, the Schottky barrier diode 16 according to the sixteenth embodiment differs from the Schottky barrier diode 15 according to the fifteenth embodiment in that a part of the drift layer 30 that is positioned outside the outer peripheral trench 63 is removed. Other basic configurations are the same as those of the Schottky barrier diode 15 according to the fifteenth embodiment, so the same reference numerals are given to the same elements, and overlapping description will be omitted. An On-current hardly flows in the part of the drift layer 30 that is positioned outside the outer peripheral trench 63, so that the drift layer 30 may be removed at this position as in the present embodiment.

While the embodiment of the present disclosure has been described, the present disclosure is not limited to the above embodiment, and various modifications may be made within the scope of the present disclosure, and all such modifications are included in the present disclosure.

The technology according to the present disclosure includes the following configuration examples but not limited thereto.

A Schottky barrier diode according to the present disclosure includes: a semiconductor substrate made of gallium oxide; a drift layer made of gallium oxide and provided on the semiconductor substrate; an anode electrode brought into Schottky contact with the drift layer; and a cathode electrode brought into ohmic contact with the semiconductor substrate. The drift layer has a center trench filled with the anode electrode. The bottom surface of the center trench is covered with an insulating film without being in contact with the anode electrode. At least a part of the side surface of the center trench is brought into Schottky contact with the anode electrode.

According to the present disclosure, the anode electrode filled in the center trench is brought into Schottky contact with the side surface of the center trench, thus making it possible to reduce the ON-resistance without increasing the impurity concentration of the drift layer.

In the present disclosure, the anode electrode may include a first anode electrode brought into Schottky contact with the upper surface of the drift layer and a second anode electrode brought into Schottky contact with the side surface of the center trench and made of a metal material different from that of the first anode electrode. This facilitates the manufacture of an anode electrode free from a void.

In the present disclosure, the drift layer may further have an outer peripheral trench filled with the anode electrode and surrounding the center trench, and the bottom surface and outer peripheral side surface of the outer peripheral trench may be covered with an insulating film without being in contact with the anode electrode. This relaxes an electric field generated at the outer peripheral bottom portion of the outer peripheral trench upon application of a backward voltage. In this case, at least a part of the inner peripheral side surface of the outer peripheral trench may be brought into Schottky contact with the anode electrode. This increases Schottky contact area to allow a further reduction in the ON-resistance.

In the present disclosure, the drift layer may further have an outer peripheral trench surrounding the center trench, and the outer peripheral trench may be filled with a semiconductor material having a conductivity type opposite to that of the drift layer. With this configuration, a depletion layer spreads around the outer peripheral trench upon application of a backward voltage. This relaxes an electric field generated at the outer peripheral bottom portion of the outer peripheral trench upon application of a backward voltage.

As described above, according to the present disclosure, the side surface of the center trench is brought into Schottky contact with the anode electrode, so that the ON-resistance of the Schottky barrier diode using oxide gallium can be reduced.

### EXAMPLES

### Example 1

A simulation model having the same structure as that of the Schottky barrier diode 2 illustrated in FIG. 3 was assumed, and a resistance value was simulated with a forward voltage applied between the anode electrode 40 and the cathode electrode 50. The dopant concentration of the semiconductor substrate 20 was set to 1×10¹⁸ cm⁻³, and the dopant concentration of the drift layer 30 was to 3×10¹⁶ cm⁻³. The thickness of the drift layer 30 was set to 7 μm. The depths of the center and outer peripheral trenches 61 and 62 were both set to 3 μm. The width of the center and outer peripheral trenches 61 and 62 in the cross section illustrated in FIG. 3 and the width of the upper surface 31 of the drift layer 30 (i.e., width of the mesa region M) were both set to 1.5 μm. The curvature radius of the curved surface 34 between the flat bottom surface 32 and the flat side surface 33 of each of the center and outer peripheral trenches 61 and 62 was set to 0.05 μm. As the insulating film 70, an HfO₂ film having a thickness of 50 nm was used. The anode electrode 40 was made of Ni, and the cathode electrode 50 was formed of a laminated film of Ti and Au. Then, the simulation was performed using the depth T of the anode electrode 40 contacting the side surface 33 of each of the center and outer peripheral trenches 61 and 62 as a variable.

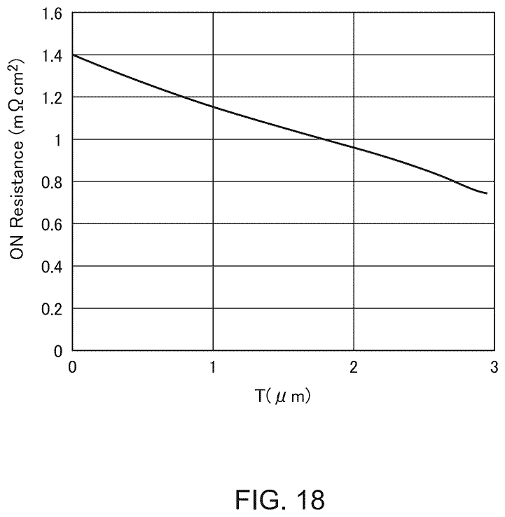

The simulation result was illustrated in FIG. 18. The graph of FIG. 18 revealed that the ON-resistance reduced with an increase in the depth T of the anode electrode 40 contacting the side surface 33 of each of the center and outer peripheral trenches 61 and 62. The backward withstand voltage was 7.5 MV/cm irrespective of the depth T.

What is claimed is:

1. A Schottky barrier diode comprising:
a semiconductor substrate made of gallium oxide;
a drift layer made of gallium oxide and provided on the semiconductor substrate;
an anode electrode brought into Schottky contact with the drift layer; and
a cathode electrode brought into ohmic contact with the semiconductor substrate,
wherein the drift layer has a center trench filled with the anode electrode,
wherein a bottom surface of the center trench is covered with an insulating film without being in contact with the anode electrode, and
wherein at least a part of a side surface of the center trench is brought into Schottky contact with the anode electrode.

2. The Schottky barrier diode as claimed in claim 1, wherein the anode electrode includes a first anode electrode brought into Schottky contact with an upper surface of the drift layer and a second anode electrode brought into Schottky contact with the side surface of the center trench and made of a metal material different from that of the first anode electrode.

3. The Schottky barrier diode as claimed in claim 1,
wherein the drift layer further has an outer peripheral trench filled with the anode electrode and surrounding the center trench, and
wherein a bottom surface and an outer peripheral side surface of the outer peripheral trench is covered with an insulating film without being in contact with the anode electrode.

4. The Schottky barrier diode as claimed in claim 2,
wherein the drift layer further has an outer peripheral trench filled with the anode electrode and surrounding the center trench, and
wherein a bottom surface and an outer peripheral side surface of the outer peripheral trench is covered with an insulating film without being in contact with the anode electrode.

5. The Schottky barrier diode as claimed in claim 3, wherein at least a part of an inner peripheral side surface of the outer peripheral trench is brought into Schottky contact with the anode electrode.

6. The Schottky barrier diode as claimed in claim 4, wherein at least a part of an inner peripheral side surface of the outer peripheral trench is brought into Schottky contact with the anode electrode.

7. The Schottky barrier diode as claimed in claim 1,
wherein the drift layer further has an outer peripheral trench surrounding the center trench, and
wherein the outer peripheral trench is filled with a semiconductor material having a conductivity type opposite to that of the drift layer.

8. The Schottky barrier diode as claimed in claim 2,
wherein the drift layer further has an outer peripheral trench surrounding the center trench, and
wherein the outer peripheral trench is filled with a semiconductor material having a conductivity type opposite to that of the drift layer.
